(19) United States
(12) Patent Application Publication
(10) Pub. No.: US 2005/0130422 A1
(43) Pub. Date: Jun. 16, 2005

(54) Method for patterning films

(75) Inventor: Steven D. Theiss, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 10/734,684

(22) Filed: Dec. 12, 2003

(51) Int. Cl. H01L 21/302; H01L 21/461

(52) U.S. Cl. 438/689

(57) ABSTRACT

A process for patterning films comprises the steps of (a) vapor depositing resist material onto a film disposed on a substrate through a repositionable aperture mask, and (b) using a subtractive process to remove the exposed portion of the film.

### FIELD

This invention relates to methods for patterning thin films.

### BACKGROUND

Integrated circuits (ICs) are made up of many electronic components or devices such as, for example, thin film transistors (TFTs) that are interconnected. Each electronic component or device can include, for example, a combination of conducting, semiconducting, and nonconducting layers that performs a specific electrical function in an IC. The layers must be patterned to form the circuits and interconnections needed for a functional device. Patterning of ICs, TFTs, and other electronic devices can be accomplished, for example, using photolithography or aperture masking techniques.

Photolithography involves exposing an ultraviolet (UV)-sensitive polymer, or “photoresist”, to UV light through a rigid glass photomask, which contains the desired pattern etched in a UV-opaque layer. Typically, a positive photoresist (that is, a photoresist that becomes more soluble in a developer upon exposure to UV light) is utilized. Positive photoresist can be exposed to UV light wherever the underlying material is to be removed so that the UV-exposed photoresist can be washed away with developer. Then, the bare portion of the underlying film layer(s) can be removed, for example, via wet chemical or dry plasma etching.

Photolithography can be difficult to carry out when fabricating ICs, TFTS, and other electronic devices on a web, however, because of the large number of layers that need to be patterned and registered. Misregistration between one circuit layer and another can adversely affect the reliability of the IC.

Patterning ICs or TFTs using aperture masking techniques involves vapor depositing device materials onto a substrate through patterns in one or more aperture masks. In some situations, however, it is preferable to deposit continuous thin films, which are patterned thereafter.

### SUMMARY

In view of the foregoing, we recognize that the patterning of thin films is one of the key challenges to the development of low-cost web-based fabrication of ICs, and that there is a need for an improved method for patterning thin films for ICs.

Briefly, in one aspect, the present invention provides a process for patterning films comprising the steps of (a) vapor depositing resist material onto a film disposed on a substrate through a repositionable aperture mask, and (b) using a subtractive process to remove the exposed portion of the film (that is, the portion of the film not covered by resist material).

As used herein, “resist material” refers to something (as a coating) that protects the film against a chemical and/or physical action of the subtractive process.

As used herein, “vapor deposition” or “vapor depositing” steps are inclusive of sputtering, thermal evaporation, electron beam evaporation, chemical vapor depositing, metalorganic chemical vapor depositing, combustion chemical vapor depositing and plasma enhanced chemical vapor and pulsed laser deposition.

The process of the invention allows aperture masking techniques to be extended to systems in which it is necessary or desirable to deposit continuous films to be patterned later.

The process of the invention is useful, for example, in situations in which a film material must be deposited at a temperature that exceeds the maximum use temperature of an aperture mask.

The process of the invention is also useful in situations in which a film requires a further processing step, which is preferably applied to the film while it is continuous (that is, before the film is patterned). For example, the process of the invention is useful in producing poly-crystalline silicon films on polymeric substrates. Methods for producing poly-crystalline films on polymeric substrates typically involve depositing amorphous silicon film onto a suitably prepared polymeric substrate, followed by a pulsed-laser annealing of the silicon film to induce melting and subsequent crystallization of the film. The laser annealing is typically accomplished using an ultraviolet (UV) laser. UV radiation is strongly absorbed by many polymeric materials, however. Therefore, if any portion of the polymeric substrate is directly exposed to the UV laser pulse, as it would be were the silicon film to be patterned prior to the laser annealing step, that-portion of the polymeric substrate could be damaged due to the heat produced by the absorbed UV radiation. It is therefore preferable to perform the laser crystallization step after the deposition of the amorphous silicon film, but prior to patterning the film.

Furthermore, the process of the invention eliminates the need for using multiple patterning methods such as, for example, aperture masking techniques for some layers and photolithography for other layers. In addition, it has been discovered that in some situations, the resist material, if allowed to remain on the finished device, can act as a protective sealant.

### DESCRIPTION OF DRAWINGS

FIGS. 1a, 1b, 1c, and 1d depict a cross-sectional schematic of an embodiment of the process of the invention.

### DETAILED DESCRIPTION

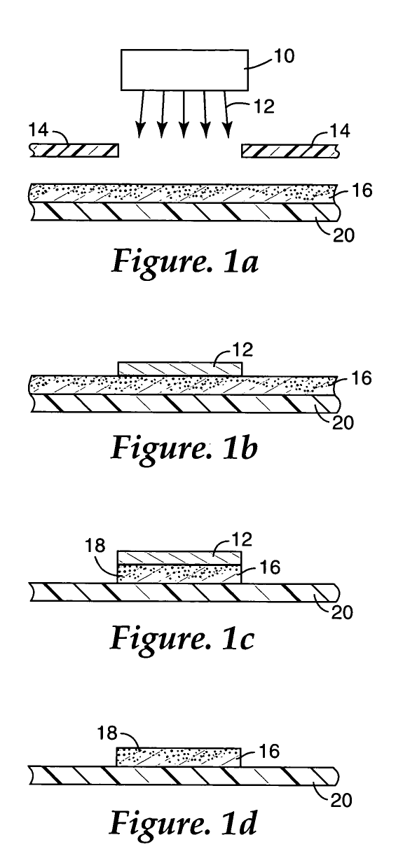

The sequence illustrated in FIGS. 1a, 1b, 1c, and 1d depicts a schematic of the process of the invention. In FIG. 1a, resist material 12 is vaporized by deposition unit 10, and deposited through repositionable aperture mask 14 onto film 16, which is disposed on substrate 20. When repositionable aperture mask 14 is removed, patterned resist material 12 is left on film 16, as shown in FIG. 1b. A subtractive process can then be used to remove the exposed portion of film 16 (that is, the portion of the film not covered by patterned resist material 12) so that only the portion of film 16 that is covered by resist material 12 is left remaining as patterned feature 18, as shown in FIG. 1c. optionally, resist material 12 can then be removed so that only patterned feature 18 remains on substrate 20, as shown in FIG. 1d.

The process of the invention can be used to pattern thin films into components that are useful in various electronic devices, TFTs, and ICs. TFTs generally include a gate electrode, a gate dielectric on the gate electrode, a source electrode and a drain electrode adjacent to the gate dielectric, and a semiconductor layer adjacent to the gate dielectric and adjacent to the source and drain electrodes (see, for example, S. M. Sze, Physics of Semiconductor Devices, 2^{nd} edition, John Wiley and Sons, page 492, New York (1981)). These components, or features, are typically provided on a substrate, and can be assembled in a variety of configurations. The process of the invention can be used to pattern any one or more of these features from thin films.

The process of the invention can be used, for example, to pattern the gate electrode of a TFT from a film of any useful conductive material. For example, the gate electrode can comprise doped silicon, or a metal, such as aluminum, copper, chromium, gold, silver, nickel, palladium, platinum, tantalum, and titanium, and transparent conducting oxides such as indium tin oxide. Conductive polymers also can be used, for example polyaniline or poly(3,4-ethylenedioxythiophene)/poly(styrene sulfonate) (PEDOT:PSS). In addition, alloys, combinations, and multilayers of these materials can be useful.

The process of the invention can also be used, for example, to pattern the gate dielectric of a TFT from a film, which is generally provided on the gate electrode. The gate dielectric electrically insulates the gate electrode from the balance of the TFT device. The gate dielectric preferably has a relative dielectric constant above about 2 (more preferably, above about 5). The dielectric constant of the gate dielectric can be relatively high, for example, 80 to 100 or higher. Useful materials for the gate dielectric can comprise, for example, organic or inorganic electrically insulating materials.

Specific examples of organic materials useful for the gate dielectric include polymeric materials, such as polyvinylidenefluoride (PVDF), cyanocelluloses, polyimides, epoxies, and the like. Other useful organic materials are described in copending application U.S. Ser. No. 10/434,377, filed on May 8, 2003. An inorganic capping layer can comprise the outer layer of an otherwise polymeric gate dielectric.

Specific examples of inorganic materials useful for the gate dielectric include strontiates, tantalates, titanates, zirconates, aluminum oxides, silicon oxides, tantalum oxides, titanium oxides, silicon nitrides, barium titanate, barium strontium titanate, and barium zirconate titanate. In addition, alloys, combinations, and multilayers of these materials can be used for the gate dielectric.

Preferred inorganic materials for the gate dielectric include aluminum oxides, silicon oxides, and silicon nitrides.

The source electrode and drain electrode of a TFT can also be patterned from a film using the process of the invention. The source electrode and drain electrode are separated from the gate electrode by the gate dielectric, while the semiconductor layer can be over or under the source electrode and drain electrode. The source and drain electrodes can be any useful conductive material. Useful materials include most of those materials described above for the gate electrode, for example, aluminum, barium, calcium, chromium, copper, gold, silver, nickel, palladium, platinum, titanium, transparent conducting oxides such as indium tin oxide, polyaniline, PEDOT:PSS, other conducting polymers, alloys thereof, combinations thereof, and multilayers thereof. Some of these materials are appropriate for use with n-type semiconductor materials and others are appropriate for use with p-type semiconductor materials, as is known in the art.

The semiconductor layer of TFTs can also be patterned from a film using the process of the invention. The semiconductor layer can comprise organic or inorganic semiconductor materials. Useful inorganic semiconductor materials include amorphous and poly silicon, tellurium, zinc oxide, zinc selenide, zinc sulfide, cadmium sulfide, and cadmium selenide (preferably, amorphous or poly silicon or zinc oxide). Useful organic semiconductor materials include acenes and substituted derivatives thereof. Particular examples of acenes include anthracene, naphthalene, tetracene, pentacene, and substituted pentacenes (preferably pentacene or substituted pentacenes, including fluorinated pentacenes). Other examples include semiconducting polymers, perylenes, fullerenes, phthalocyanines, oligothiophenes, polythiophenes, polyphenylvinylenes, polyacetylenes, metallophthalocyanines and substituted derivatives. Useful bis-(2-acenyl) acetylene semiconductor materials are described in copending application U.S. Ser. No. 10/620027, filed on Jul. 15, 2003.

Substituted derivatives of acenes include acenes substituted with at least one electron-donating group, halogen atom, or a combination thereof, or a benzo-annellated acene or polybenzo-annellated acene, which optionally is substituted with at least one electron-donating group, halogen atom, or a combination thereof. The electron-donating group is selected from an alkyl, alkoxy, or thioalkoxy group having from 1 to 24 carbon atoms. Preferred examples of alkyl groups are methyl, ethyl, n-propyl, isopropyl, n-butyl, sec-butyl, n-pentyl, n-hexyl, n-heptyl, 2-methylhexyl, 2-ethylhexyl, n-octyl, n-nonyl, n-decyl, n-dodecyl, n-octadecyl, and 3,5,5-trimethylhexyl. Substituted pentacenes and methods of making them are taught in U.S. patent application Publication Nos. 03-0105365-A1 and 03-010779-A1.

Further details of benzo-annellated and polybenzo-annellated acenes can be found in the art, for example, in NIST Special Publication 922 “Polycyclic Aromatic Hydrocarbon Structure Index”, U.S. Govt. Printing Office, by Sander and Wise (1997).

The thin film electrodes (that is, the gate electrode, source electrode, and drain electrode) and dielectric can be provided by any useful means such as, for example, plating, ink jet printing, or vapor deposition. The semiconductor layer can be provided by any useful means such as, for example, solution deposition, spin coating, printing techniques, or vapor deposition.

The patterning of the thin film electrodes, dielectric, and semiconductor layer can be accomplished using the method of the invention, or by using known methods such as aperture masking, additive photolithography, subtractive photolithography, printing, microcontact printing, and pattern coating.

The method of the invention can also be used to pattern optional layers such as, for example, surface treatment layers or sealing layers that are sometimes included in TFTs.

Surface treatment layers are typically disposed between the semiconductor (usually an organic semiconductor) and the gate dielectric. Surface treatment layers include, for example, nonfluorinated polymeric layers such as those described in U.S. patent application Publication No. 2003/0102471 (Kelley et al.), self-assembled monolayers such as those described in U.S. Pat. No. 6,433,359 (Kelley et al.), and siloxane polymeric layers such as those described in U.S. Pat. No. 6,617,609 (Kelley et al.). Surface treatment layers can provide TFTs with one or more improvements over known devices, including improvements in properties such as threshold voltage, subthreshold slope, on/off ratio, and charge-carrier mobility. In addition, large improvements in at least one property, such as charge-carrier mobility, can be achieved with surface treatment layers, while maintaining other TFT properties within desirable ranges.

Sealing layers typically cover at least a portion of the semiconductor (preferably, the sealing material also covers at least a portion of the source and drain electrodes; more preferably, the sealing material covers the active portion of the TFT). Useful materials for sealing layers include materials that can be vapor deposited and have a resistivity of at least 10× that of the semiconductor layer (preferably at least 100×). Useful sealing materials are described, for example, in copending application U.S. Ser. No. 10/642919, filed on Aug. 13, 2003. Sealing layers can insulate the device from other electronic components, and isolate it from environmental contaminants such as humidity and water.

A substrate typically supports a TFT during manufacturing, testing, and/or use. For example, one substrate may be selected for testing or screening various embodiments while another substrate is selected for commercial embodiments. Optionally, the substrate can provide an electrical function for the TFT. Useful substrate materials include organic and inorganic materials. For example, the substrate can comprise inorganic glasses, ceramic foils, polymeric materials (for example, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(phenylene sulfide) (PPS)), filled polymeric materials (for example, fiber-reinforced plastics (FRP)), fibrous materials, such as paper and textiles, and coated or uncoated metallic foils.

A flexible substrate can be used. This allows for roll processing, which may be continuous, providing economy of scale and economy of manufacturing over flat and/or rigid substrates. Flexible substrates are preferably capable of wrapping around the circumference of a cylinder of less than about 50 cm diameter (preferably, less than about 25 cm diameter; more preferably, less than about 10; most preferably, less than about 5 cm) without distorting or breaking. The force used to wrap the flexible substrate of the invention around a particular cylinder typically is low, such as by unassisted hand (that is, without the aid of levers, machines, hydraulics, and the like). Preferred flexible substrates can be rolled upon themselves.

Resist material is deposited onto the film through a repositionable aperture mask. Repositionable aperture masks enable deposition of a resist material and, simultaneously, formation of the resist material in a desired pattern. Preferably, the repositionable aperture mask is reusable.

The resist material can be deposited through the pattern of a repositionable aperture mask formed from a polymer material such as, for example, polyimide or polyester. Polymer masks typically have a thickness of between about 5 microns and about 50 microns. In some instances, the use of polymeric materials for aperture masks can provide advantages over other materials, including ease of fabrication of the aperture mask, reduced cost of the aperture mask, and other advantages. Polymer aperture masks are flexible and are generally less prone to damage due to the accidental formation of creases or permanent bends. In addition, polymer aperture masks are less damaging to the continuous film. The use of flexible polymeric aperture masks is discussed in copending applications U.S. Ser. No. 10/076,003, U.S. Ser. No. 10/076,005, and U.S. Ser. No. 10/076,174, all filed on Feb. 13, 2002.

However, non-polymeric materials such as, for example, silicon, metals, or crystalline materials can be used for repositionable aperture masks, and are, in some instances preferable. For example, non-polymeric materials are preferable when resist material must be deposited at a temperature that exceeds the maximum use temperature of a polymeric aperture mask.

The arrangement and shape of deposition apertures are subject to wide variation depending upon the TFT and circuit layout envisioned by the user. Laser ablation techniques can be used to define the pattern of deposition apertures in polymer aperture masks. Alternatively, if a repositionable aperture mask is formed from a silicon wafer, the pattern of apertures can be created using reactive ion etching or laser ablation. Repositionable metal aperture masks can be made by a variety of techniques including, for example, conventional machining, micromachining, diamond machining, ion beam etching, and electric discharge machining (EDM) or spark-erosion machining.

A deposition station can be used for vapor depositing resist material through an aperture onto a film. The deposition chamber is typically a vacuum chamber. After a repositionable aperture mask is placed in proximity to a film, the resist material is vaporized by a deposition unit. The deposition unit can include a boat of material that is heated to vaporize the resist material, or any other suitable means for e-beam evaporation, pulsed laser deposition, sputtering or the like. The vaporized resist material deposits on the film through the aperture(s) of a repositionable aperture mask in a pattern defined by the aperture mask.

When flexible aperture masks are made sufficiently large, for example, to include a pattern that has large dimensions, a sag problem can arise. In particular, when such a flexible aperture mask is placed in proximity to a film, the flexible aperture mask can sag as a result of gravitational pull on the flexible aperture mask. This problem is usually most apparent when the aperture mask is positioned underneath the film. Moreover, the sag problem can compound as the flexible aperture mask is made larger and larger.

A variety of techniques can be used to address the sag problem or otherwise control sag in aperture masks during a deposition process. For example, the flexible aperture mask can have a first side that can removably adhere to a surface of a deposition substrate to facilitate intimate contact between the aperture mask and the film during the deposition process. In particular, the first side can include a pressure sensitive adhesive that can be removed after the deposition process.

Another way to control sag is to use magnetic force. For example, an aperture mask can comprise both a polymer and magnetic material. The magnetic material can be coated or laminated on the polymer, or can be impregnated into the polymer. For example, magnetic particles can be dispersed within a polymeric material used to form the aperture mask. When a magnetic force is used, a magnetic field can be applied within a deposition station to attract or repel the magnetic material in a manner that controls sag in the aperture mask.

Yet another way to control sag is the use of electrostatics. The aperture mask can comprise a polymer that is electrostatically coated or treated. A charge can be applied to the aperture mask, the film, or both to promote electrostatic attraction in a manner that controls sag in the aperture mask.

Still another way to control sag is to stretch the aperture mask. A stretching unit can be implemented to stretch the aperture mask by an amount sufficient to reduce, eliminate, or otherwise control sag. As the mask is stretched tightly, sag can be reduced. In order to control sag using stretching, the aperture mask needs to have an acceptable coefficient of elasticity.

Additionally, the concept of stretching a polymeric aperture mask can also be used to properly align the aperture mask for a deposition process.

Another challenge using aperture mask deposition techniques relates to the difficulty in aligning the aperture masks with deposited layers on the film. Moreover, as more and more layers of a TFT or circuit are deposited, the alignment problem can be compounded.

Aperture masks can therefore comprise a mask substrate having alignment edges. A pattern of deposition apertures can be defined in the mask substrate in relation to the alignment edges such that spatial alignment of the edges of the mask substrate aligns the pattern for the deposition process. If each mask in a mask set is formed with the same alignment edges, the masks can be easily aligned relative to deposited layers during sequential depositions.

The substrate can include alignment edges that substantially correspond to the alignment edges of the aperture mask. In this manner, spatial alignment of the edges of the aperture mask and the edges of the deposition substrate properly aligns the pattern relative of the deposition apertures relative to the deposition substrate for the deposition process.

Resist materials that are useful in the method of the invention vary depending upon the material of the film to be patterned, and the subtractive process to used. Useful resist materials include organic and inorganic materials that can be vapor deposited.

Representative examples of useful organic resist materials include polymeric material that can be vapor deposited such as, for example, polyvinylidenefluoride (PVDF), polystyrene, polyimides, epoxies, and the like. Monomeric precursors (reactive monomers) that can be vapor deposited and subsequently cured (for example, by UV or e-beam curing) can also be used. In addition, small molecules such as, for example, organic glasses, crystalline organics, and the like can be used.

Parylene is also a useful organic resist material. Parylene is a general term used to describe a class of poly-p-xylenes that are derived from a dimer having the following structure: 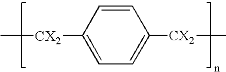
wherein X is H or halogen. Parylene coatings are generally applied from their respective dimers by a deposition process in which the dimer is vaporized, pyrolyzed (that is, cleaved into the monomer vapor form), and supplied to a deposition chamber. The deposition process is known in the art and is described, for example, in U.S. Pat. No. 5,536,319.

As used herein, “parylene” includes all of the parylene coatings such as, for example, 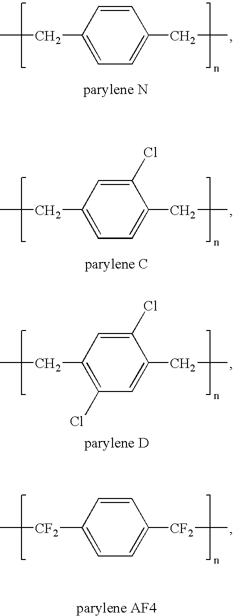
and substituted parylenes.

Useful inorganic resist materials include metal oxides and metal nitrides, inorganic semiconductors, and metals. Representative examples of useful metal oxides and metal nitrides include, for example, silicon oxides, aluminum oxides, tantalum oxides, titanium oxides, silicon nitrides, barium titanate, barium strontium titanate, barium zirconate titanate, and the like. Representative examples of useful inorganic semiconductors include, for example, silicon (poly-Si, amorphous-Si, or amorphous-Si:H), zinc oxide, germanium, and the like. Representative examples of useful metals include, for example, aluminum, chromium, tungsten, and the like. In addition, alloys and combinations of these materials can be used.

A subtractive process is used to remove the exposed portion of the film (that is, the portion of the film not covered by the resist material). Useful subtractive processes include, for example, wet chemical etching, the use of solvents, dry etching (that is, plasma/reactive ion etching), laser ablation, and the like.

Wet chemical etching typically involves the removal of material by immersing the substrate in a liquid bath of a chemical etchant or by spraying the substrate with a chemical etchant that reacts with the film. Representative examples of etchants include HF, HF:NH₄F, KOH, ethylenediamine pyrocatechol (EDP), CsOH, NaOH, and hydrazine (N₂H₄—H₂O) for silicon; HCl:glycerin, iodine, KI:I₂H₂0, and HNO₃ for metals; and HF and HCl for metal oxides or nitrides.

Solvent removal typically involves exposing the substrate to a solvent in which the film is soluble. Useful solvents include, for example, aqueous and organic solvents such as water, acetone, toluene, hexane, heptane, cyclohexane, and the like, and mixtures thereof.

Dry etching is performed either by plasma or reactive ions. Dry etching generally involves exposing the material to be removed to a reactive plasma, which etches the material through a combination of physical and chemical processes. A plasma can be generated in an etchant gas using techniques such as, for example, radio frequency energy, microwave energy, or microwave energy combined with magnetic confinement. Useful etchant gases include, for example, chlorohydrocarbons (for example, CFCl₃, CF₂Cl₂, and CF₃Cl), halocarbons (for example, CCl₄, CF₄, CHCl₃, and CHF₃), fluorine-based gases (for example, SF₆, NF₃, and SiF₄), chlorine-based gases (for example, Cl₂, BCl₃, and SiCl₄), and bromine-based gases (for example, Br₂ and HBr).

Laser ablation involves the direct removal of material by exposing portions of the material to laser light of an intensity and wavelength sufficient to decompose the material. Typically, an ultraviolet (UV) laser is used; however, the illumination can be any kind of light, such as infrared or visible light. Any type of suitable laser such as, for example, CO₂ lasers or excimer lasers can be used. Excimer lasers are particularly useful. Any type of excimer laser (for example, F₂, ArF, KrCl, XeCl, or KrF) can be used.

The subtractive process to be used will depend upon the film material and the resist material utilized, and the degree of selectivity of a particular subtractive process between the removal of the film material and the removal of the resist material (that is, the removal process should selectively remove the film material rather than the resist material). Appropriate subtractive processes will be apparent to one skilled in the art. Representative examples of suitable subtractive processes that can be used with typical film/resist combinations include those listed in the following table.

| Resist Material | Film | Subtractive Process |
|---|---|---|
| Silicon dioxide | Amorphous silicon | Wet etching with |
| | | potassium hydroxide |
| Silicon nitride | Amorphous silicon | Wet etching with |
| | | potassium hydroxide |
| Silicon dioxide | Silicon | Dry etching with |
| | | sulfur hexafluoride |
| Amorphous silicon | Silicon dioxide | Wet etching with |
| | | hydrogen fluoride |
| Polyimide | Indium-doped tin | Wet etching with |
| | oxide | hydrochloric acid |
| Polyimide | Chromium | Wet etching with |
| | | acetic acid/ceric |
| | | ammonium nitrate |
| | | solution |
| Silicon | Metal oxide or | Wet etching with |
| | nitride | hydrofluoric acid |
| Aluminum | Silicon | Laser ablation |
| Aluminum oxide | Pentacene | Solvent removal |
| | | with acetone |

Optionally, after patterning a film using the process of the invention, the resist material can be removed. It is preferable to remove the resist material, for example, when it would be between device layers because device performance could be negatively affected. The resist material can be removed, for example, using the subtractive processes discussed above. Again, appropriate techniques will depend upon the particular resist material and the particular film material utilized. However, the subtractive process should now selectively remove the resist material rather than the film material.

In some situations, however, it is desirable to leave the resist material intact to protect the TFT or IC as a sealant. Resist materials such as, for example, polymeric materials, parylene, metal oxides, and metal nitrides can provide a lasting barrier to the environment and allow for further processing, including wet processing, to be carried out on top of the device.

### EXAMPLE

Objects and advantages of this invention are further illustrated by the following example, but the particular materials and amounts thereof recited in this example, as well as other conditions and details, should not be construed to unduly limit this invention.

300 nm of hydrogenated amorphous silicon (a-Si:H) was sputtered onto a 2 inch (5.08 cm)×3 inch (7.62 cm) clean glass slide using radio frequency (RF) sputtering at 13.56 MHz. The target used was a crystalline silicon magnetron sputtering target (available from MAT-VAC Technology, Daytona Beach, Fla.). The sputtering conditions were as follows. Sputtering power was 700 Watts forward RF power, 38 Watts reflected RF power. The substrate temperature was held at 200° C. Presputtering was done at 700 Watts for 15 minutes followed by 12 minutes of deposition at 700 Watts. The sputtering pressure was 1.93 mTorr with gas flow rates of 6 sccm Ar and 1 sccm of H₂ (1.8 mTorr partial pressure of Ar and 0.13 mTorr partial pressure of H₂).

A polyimide aperture mask (made essentially as described in copending application U.S. Ser. No. 10/076,174, filed Feb. 14, 2002) was placed in intimate contact with the a-Si:H film coated glass slide. 130 nm of silicon dioxide (SiO₂) was deposited patternwise through the aperture mask and on top of the a-Si:H film to act as a resist. The SiO₂ was sputtered from a silicon dioxide magnetron target (also available from MAT-VAC Technologies) at 13.56 MHz under the following conditions. Sputtering power was 400 Watts forward RF power, 0 Watts reflected RF power. The slide temperature was held at 150° C. Presputtering was done at 400 Watts for 24 minutes followed by 22 minutes of deposition at 400 Watts. The sputtering pressure was 1.28 mTorr with gas flow rates of 3 sccm Ar and 0.5 sccm of O₂ (1.0 mTorr partial pressure of Ar and 0.28 mTorr partial pressure of O₂).

The patternwise coated slide was removed from the chamber, the aperture mask was removed, and then the slide was immersed in a 50:50 KOH:DI water etching solution at room temperature to patternwise etch the a-Si:H film. The slide was removed from the etching solution when the a-Si:H film was visually observed to have been removed. Under microscopic inspection, it was observed that the areas of the a-Si:H film covered with the SiO₂ pattern were not etched (that is, the a-Si:H film was patterned).

The referenced descriptions contained in the patents, patent documents, and publications cited herein are incorporated by reference in their entirety as if each were individually incorporated. Various modifications and alterations to this invention will become apparent to those skilled in the art without departing from the scope and spirit of this invention. It should be understood that this invention is not intended to be unduly limited by the illustrative embodiments and examples set forth herein and that such examples and embodiments are presented by way of example only with the scope of the invention intended to be limited only by the claims set forth herein as follows.

1. A process for patterning films comprising the steps of:
(a) vapor depositing resist material onto a film disposed on a substrate through a repositionable aperture mask, and
(b) using a subtractive process to remove the exposed portion of said film.

2. The process of claim 1 further comprising the step of removing said resist material.

3. The process of claim 1 wherein said resist material is selected from the group consisting of vapor-depositable polymers, parylene, metal oxides, metal nitrides, inorganic semiconductors, and metals.

4. The process of claim 3 wherein said resist material is silicon dioxide.

5. The process of claim 1 wherein said film is selected from the group consisting of organic and inorganic semiconductor materials, organic and inorganic dielectric materials, metals, metal oxides and nitrides, and transparent conducting oxides.

6. The process of claim 5 wherein said film is selected from the group consisting of organic and inorganic semiconductor materials.

7. The process of claim 6 wherein said film is selected from the group consisting of pentacene, substituted pentacene, amorphous and poly silicon, and zinc oxide.

8. The process of claim 1 wherein said subtractive process is selected from the group consisting of wet chemical etching, solvent removal, dry etching, and laser ablation.

9. The process of claim 1 wherein said aperture mask is reusable.

10. The process of claim 1 wherein said aperture mask is a polymeric aperture mask.

11. The process of claim 10 wherein said polymeric aperture mask comprises polyimide.

12. The process of claim 1 wherein said substrate is a flexible substrate.

13. The process of claim 12 wherein said flexible substrate is capable of wrapping around the circumference of a cylinder of less than about 50 cm diameter without distorting or breaking.

14. A thin film transistor wherein one or more transistor features were patterned from a film using the process of claim 1.

15. A thin film transistor wherein the semiconductor was patterned from a film using the process of claim 1.
